(19) United States
(12) Patent Application Publication
(10) Pub. No.: US 2016/0219727 A1
(43) Pub. Date: Jul. 28, 2016

(54) Adaptable Mobile Device Stand

(71) Applicant: Joel McMahon, Atlanta, GA (US)

(72) Inventor: Joel McMahon, Atlanta, GA (US)

(21) Appl. No.: 14/604,709

(22) Filed: Jan. 24, 2015

(51) Int. Cl. H05K 5/02; F16M 11/20; F16M 11/24

(52) U.S. Cl. CPC H05K 5/0204; F16M 11/24; F16M 11/2035

(57) ABSTRACT

An adaptable mobile device stand is provided that includes (1) a moldable fill material that retains shape once molded, and (2) a bladder for enclosing the moldable fill material, so that the bladder and the moldable fill material together form a shape that forms a viewing angle when the mobile computing device is pressed against the bladder, and the bladder is formed from a material having a coefficient of friction sufficient to prevent the mobile computing device from sliding away from the bladder, so that the mobile computing device is maintained at the formed viewing angle.

### BACKGROUND

This invention pertains to mobile communication devices. More particularly, this invention pertains to an adaptable mobile device stand for positioning smart phones and other mobile communication devices at desired viewing angles.

Mobile communication devices, such as smart phones, tablet computers, e-readers and the like proliferate the marketplace. Consumers use these devices at home, in office, at restaurants, at coffee shops, in school classrooms, lecture halls, and the like. A common problem is positioning the mobile device in a manner for viewing the information on the screen without the mobile device sliding out of position or onto the work surface.

Mobile electronic communication devices require a holder or stand to allow for ergonomic viewing of the information screen. Presently, mobile devices without a stand or other propping device require the use of both hands to hold and operate or otherwise be positioned flat on the user's work surface. In order to watch a video, read an article, or otherwise utilize the many features of the device while keeping hands free for other activities, the mobile electronic communication device must allow for convenient viewing of the information screen. Current solutions include cases that include a fixed stand for viewing, but such an apparatus often proves bulky and uncomfortable in pockets of the user. Such will be an increasing annoyance to many who carry their mobile devices in their pockets because of the increasing size of such devices.

### BRIEF SUMMARY

According to one embodiment of the present invention, an adaptable mobile device stand is provided. The adaptable mobile device stand includes (1) a moldable fill material that retains shape once molded, and (2) a bladder for enclosing the moldable fill material, so that the bladder and the moldable fill material together form a shape that forms a viewing angle when the mobile computing device is pressed against the bladder, and the bladder is formed from a material having a coefficient of friction sufficient to prevent the mobile computing device from sliding away from the bladder, so that the mobile computing device is maintained at the formed viewing angle.

In one embodiment, the moldable fill material is kinetic sand. In another embodiment, the moldable fill material is microparticles.

In one embodiment, the bladder is latex. In another embodiment, the bladder is rubber.

Other systems, methods, features and advantages of the present invention will be or become apparent to one with skill in the art upon examination of the following drawings and detailed description. It is intended that all such additional systems, methods, features and advantages be included within this description and be within the scope of the present disclosure.

### BRIEF DESCRIPTION OF THE DRAWINGS

The above-mentioned features will become more clearly understood from the following detailed description read together with the drawings in which:

FIG. 1 is a perspective view of an adaptable mobile device stand;

FIG. 2 is a side view of the adaptable mobile device stand of FIG. 1;

FIG. 3 is a cut-away view of the adaptable mobile device stand;

FIG. 4 is another cut-away view of an alternative embodiment of an adaptable mobile device stand;

FIG. 5 is a perspective view illustrating use of the adaptable mobile device stand for positioning a smart phone for a generally upright viewing angle;

FIG. 6 is a side view illustrating use of the adaptable mobile device stand for positioning a smart phone for the viewing angle of FIG. 5;

FIG. 7 is a perspective view illustrating use of the adaptable mobile device stand for positioning a smart phone for a generally horizontal viewing angle; and

FIG. 8 is a side view illustrating use of the adaptable mobile device stand for positioning a smart phone for the viewing angle of FIG. 7.

### DETAILED DESCRIPTION

An adaptable mobile device stand for positioning smart phones and other mobile communication devices at desired viewing angles is disclosed. The mobile device stand provides for easily positioning a smart phone or other mobile communication device at a desired location and viewing angle.

Mobile electronic communication devices such as smart phones, tablets, and such like, require a holder or stand to allow for ergonomic viewing of the information screen. Presently, mobile devices without a stand or other propping device require the use of both hands to effectively hold and operate. Otherwise the mobile device must be positioned flat on the user's work surface for effective use. In order to watch a video, read an article, or otherwise utilize the many features of the mobile device while keeping hands free for other activities, the mobile electronic communication device must allow for convenient viewing of the information screen. Existing solutions include cases that include a fixed stand for viewing, but such an apparatus often proves bulky and uncomfortable in pockets of the user. Such will be an increasing annoyance to many who carry their mobile devices in their pockets because of the increasing size of such devices.

The adaptable mobile device stand provides a completely adjustable surface on which a smart phone or other mobile communication device rests while also providing for multiple viewing angles of the viewing screen. The surface of the adaptable mobile device stand is made from a material with a high enough coefficient of friction so that the mobile communication device effectively sticks to the surface without sliding. One embodiment of the adaptable mobile device stand is a sphere or ball shape similar to a balloon and filled with a material that is formable into a desired shape that is retained during use.

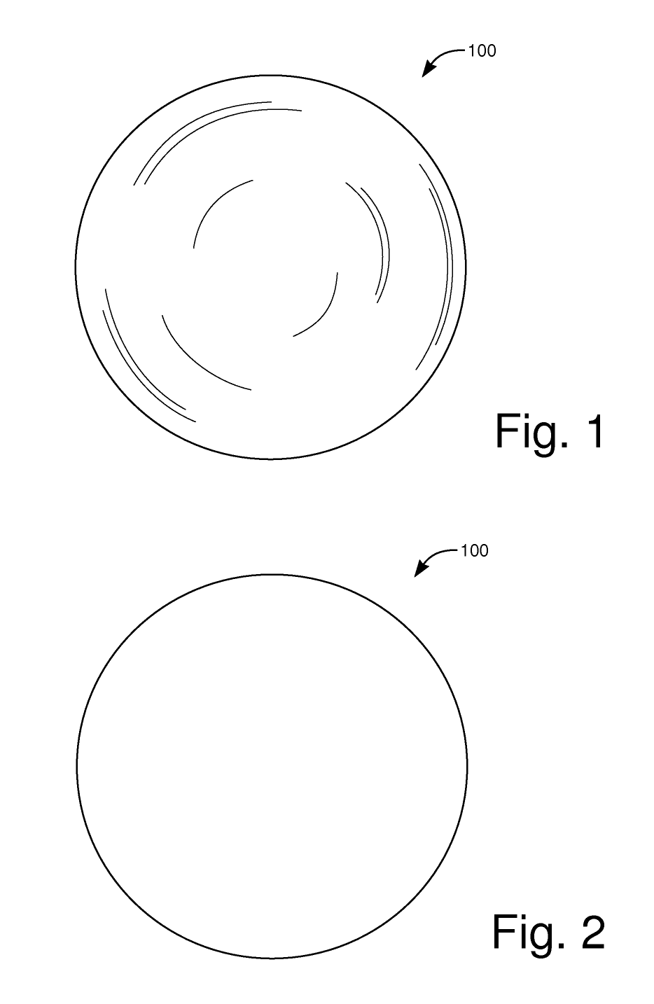

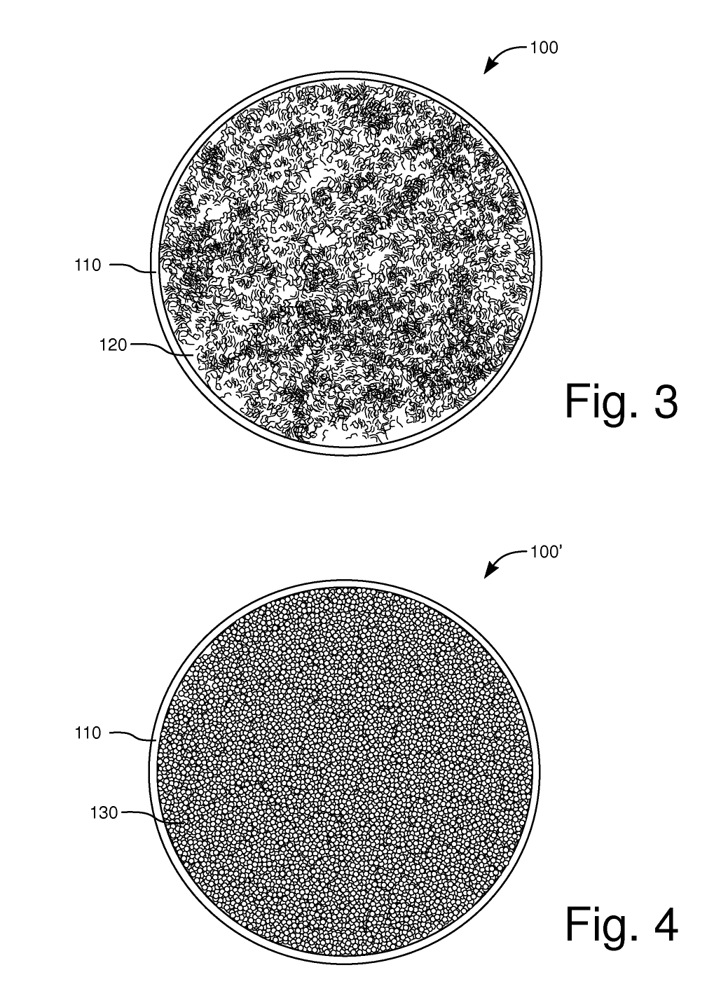

FIG. 1 is a perspective view of an adaptable mobile device stand 100, and FIG. 2 is a side view of the adaptable mobile device stand 100. FIG. 3 is a cut-away view of the adaptable mobile device stand 100. FIG. 4 is another cut-away view of an alternative embodiment of an adaptable mobile device stand 100′. The adaptable mobile device stand 100 includes a balloon like bladder 110 that typically encloses a moldable filling material. In various embodiments, the moldable filling material includes kinetic sand 120, micro-particles 130, or other loose particles that are moldable. In various embodiments, the moldable material is a material that is readily moldable into a particular desired shape and retains that shape once molded.

In various embodiments, the bladder 110 is formed from a material having a high enough coefficient of friction so that a smart phone, tablet, or other mobile computing device does not slide or skid when placed on or against the adaptable mobile device stand 100. In one embodiment, the bladder 110 is formed of latex material. In another embodiment, the bladder 110 is formed of rubber material. Those skilled in the art will recognize that other similar such materials can be used to provide such an appropriate coefficient of friction without departing from the spirit and scope of the present disclosure.

In one embodiment, as illustrated in FIG. 3, the moldable filling material is kinetic sand 120. Kinetic sand 120 is a malleable sand product that is 98% sand and 2% polydimethylsiloxane, and mimics wet sand. The polydimethylsiloxane (also dimethicone) is a silicon-based polymer known by its unusual flow properties. This makes kinetic sand different from regular sand. Kinetic sand 120 is visually similar to brown-sugar, can be molded, sticks to itself, but does not stick to most other materials, and does not dry out. This makes kinetic sand 120 a very suitable material for inserting into the bladder 110 of the adaptable mobile device stand 100. Since the kinetic sand 120 will not dry out, the adaptable mobile device stand 100 will not become stiff and unusable over time.

The combination of the kinetic sand 120 within the bladder 110 provides a spherical object that is malleable to both the surface on which it is placed and the mobile computing device that is supported. The adaptable mobile device stand 100 is easily pressed and/or molded so that the mobile computing device is supported at the desired viewing angle.

In another embodiment, as illustrated in FIG. 4, the alternative adaptable mobile device stand 100′ includes a moldable filling material that are microparticles 130. Microparticles 130 are particles between 0.1 and 100 micrometers in size. Microparticles 130 are commercially available in materials such as ceramics, glass, polymers, and metals. The size of microparticles 130 are defined in various ways as will be understood by those of skill in the art.

In the illustrated embodiment, microparticles 130 are of such size and material that when inserted within the bladder 110, the combination provides the malleable properties for conforming to both the surface on which the adaptable mobile device stand 100 is placed and the mobile computing device that is supported. As above, the alternative adaptable mobile device stand 100′ is easily pressed and/or molded so that the mobile computing device is supported at the desired viewing angle.

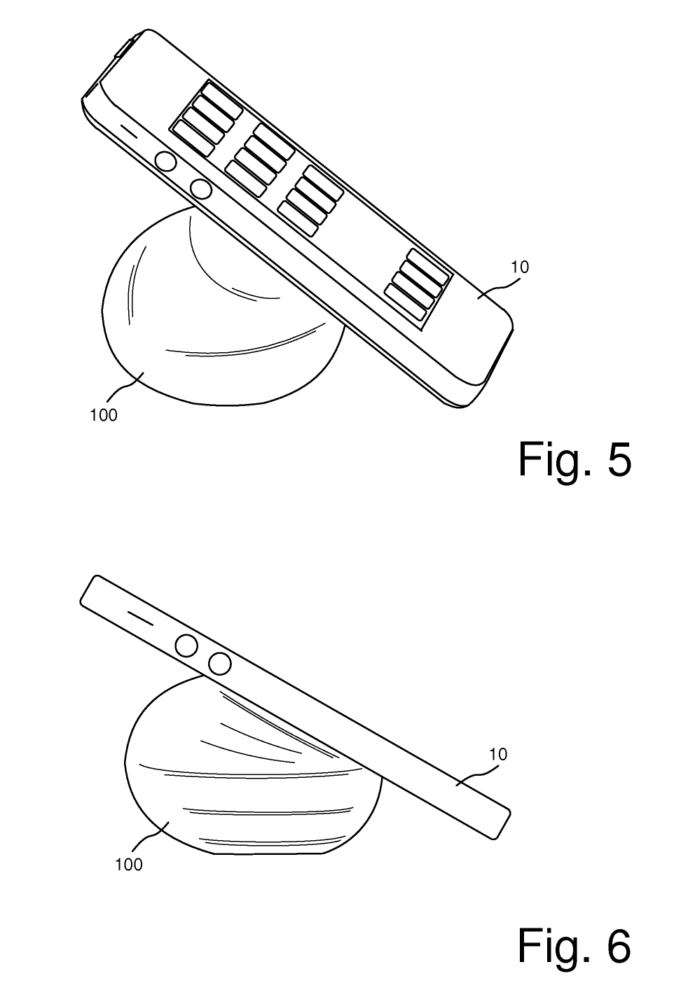

FIG. 5 is a perspective view illustrating use of the adaptable mobile device stand 100 for positioning a smart phone 10 for a generally upright viewing angle, and FIG. 6 is a side view illustrating use of the adaptable mobile device stand 100 for positioning the smart phone 10 for that same viewing angle. As shown in the illustrated embodiment, the adaptable mobile device stand 100 is pressed against the surface on which it rests such as a desk, table, or computer stand, for example. A mobile computing device such as a smart phone 10 is then pressed against the adaptable mobile device stand 100 as shown.

It should be noted that the adaptable mobile device stand 100 is pliable such that a portion of the stand 100 lies flat on the surface and a portion of the stand 100 is flattened against the underside or backside of the smart phone 10 (or other mobile computing device). As such, the adaptable mobile device stand 100 forms a wedge between the surface and the smart phone 10 so that smart phone 10 is positioned at any desired viewing angle. Adjustment of the viewing angle is as simple as removing the smart phone 10, squeezing or pressing the adaptable mobile device stand 100 to a different or more appropriate beginning shape, and then replacing the smart phone 10 against the adaptable mobile device stand 100 at the desired viewing angle.

Additionally, the adaptable mobile device stand 100 provides for easily propping or positioning the smart phone 10 for viewing the information on the screen, all the while preventing the smart phone 10 from sliding down onto the work surface.

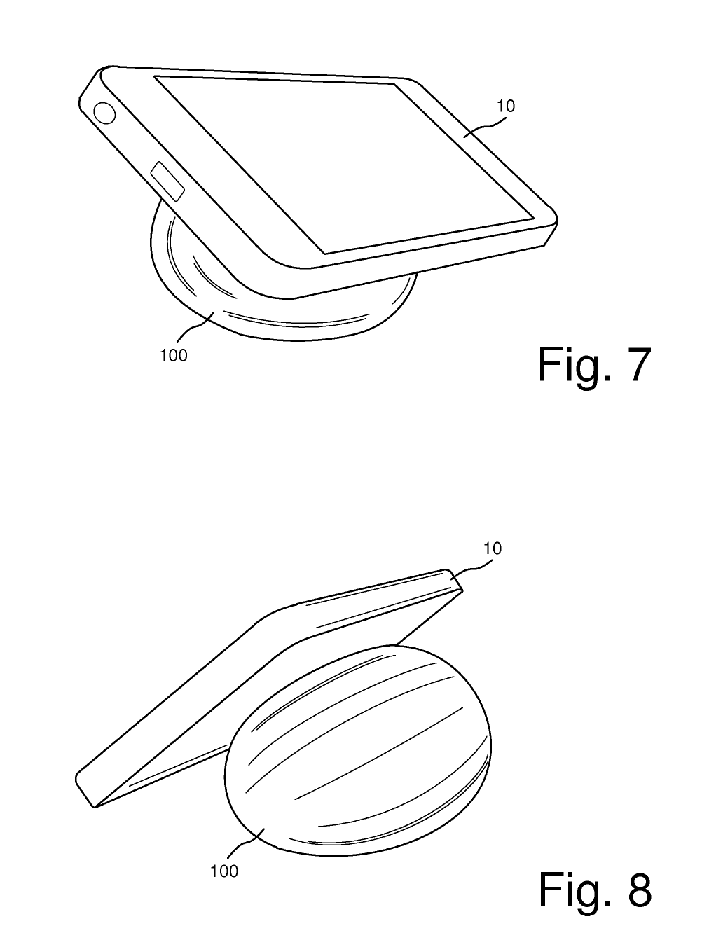

FIG. 7 is a perspective view illustrating use of the adaptable mobile device stand 100 for positioning a smart phone 10 for a generally horizontal viewing angle, and FIG. 8 is a side view illustrating use of the adaptable mobile device stand 100 for positioning the smart phone 10 for that same viewing angle. As above, and as shown in the illustrated embodiment, the adaptable mobile device stand 100 is pressed against the surface on which it rests such as a desk, table, or computer stand, for example. In FIG. 7, the adaptable mobile device stand 100 has been pressed into a more elongated shape so that the smart phone 10 is oriented in a generally horizontal direction, such as for viewing videos with more screen area (as in HD movies, for example). As noted above, a mobile computing device such as a smart phone 10 is pressed against the adaptable mobile device stand 100 as shown.

Again, and as noted above, the adaptable mobile device stand 100 is pliable such that a portion of the stand 100 lies flat on the surface and a portion of the stand 100 is flattened against the underside or backside of the smart phone 10 (or other mobile computing device). As such (again), the adaptable mobile device stand 100 forms a wedge between the surface and the smart phone 10 so that smart phone 10 is positioned at any desired viewing angle. As above, adjustment of the viewing angle is as simple as removing the smart phone 10, squeezing or pressing the adaptable mobile device stand 100 to a different or more appropriate beginning shape, and then replacing the smart phone 10 against the adaptable mobile device stand 100 at the desired viewing angle.

Again, as noted above, the adaptable mobile device stand 100 provides for easily propping or positioning the smart phone 10 for viewing the information on the screen, all the while preventing the smart phone 10 from sliding down onto the work surface.

From the foregoing description, it will be recognized by those skilled in the art that an adaptable mobile device stand 100 has been provided. The adaptable mobile device stand 100 is an omnipositional mobile device stand in that the mobile computing devices can be positioned to obtain any desired viewing angle. The adaptable mobile device stand 100 also provides a friction-surface to prevent undesired movement of the mobile computing device.

The viewing angle for a particular mobile computing device are readily adjustable by simply squeezing and/or re-pressing the shape of the adaptable mobile device stand 100.

The adaptable mobile device stand 100 includes a moldable fill material 120, 130 that retains shape once molded, and a bladder 110 for enclosing the moldable fill material 120, 130, so that the bladder 110 and the moldable fill material 120, 130 together form a shape that forms a viewing angle when the mobile computing device 10 is pressed against the bladder 110, and the bladder 110 is formed from a material having a coefficient of friction sufficient to prevent the mobile computing device 10 from sliding away from the bladder 110, so that the mobile computing device 10 is maintained at the formed viewing angle

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

1. A mobile device stand for supporting a mobile computing device, said mobile device stand comprising:
a moldable fill material that retains shape once molded, the moldable fill material further comprising kinetic sand; and
a bladder for enclosing the moldable fill material, the bladder and the moldable fill material together comprising a shape to form a viewing angle when the mobile computing device is pressed against the bladder, the bladder formed from a material having a coefficient of friction sufficient to prevent the mobile computing device from sliding away from the bladder,
whereby the mobile computing device is maintained at the formed viewing angle.

2. (canceled)

3. The mobile device stand of claim 1, the moldable fill material further comprising microparticles.

4. The mobile device stand of claim 1, wherein the bladder is formed from latex.

5. The mobile device stand of claim 1, wherein the bladder is formed from rubber.

6. A mobile device stand for supporting a mobile computing device, said mobile device stand comprising:
a moldable fill material that retains shape once molded, the moldable fill material further comprising kinetic sand; and
a bladder for enclosing the moldable fill material to form a viewing angle when the mobile computing device is pressed against the bladder,
whereby the mobile computing device is maintained at the formed viewing angle.

7. (canceled)

8. (canceled)

9. The mobile device stand of claim 6, the moldable fill material further comprising microparticles.

10. The mobile device stand of claim 6, wherein the bladder is formed from a material having a coefficient of friction sufficient to prevent the mobile computing device from sliding away from the bladder

11. The mobile device stand of claim 10, wherein the bladder is formed from latex.

12. The mobile device stand of claim 10, wherein the bladder is formed from rubber.

13. A mobile device stand for supporting a mobile computing device, said mobile device stand comprising:
a moldable fill material that retains shape once molded, the moldable fill material further comprising a sand mixture that is approximately 98 percent sand and 2 percent polydimethylsiloxane; and
a bladder for enclosing the moldable fill material, the bladder and the moldable fill material together comprising a shape to form a viewing angle when the mobile computing device is pressed against the bladder, the bladder formed from a material having a coefficient of friction sufficient to prevent the mobile computing device from sliding away from the bladder,
whereby the mobile computing device is maintained at the formed viewing angle.

14. The mobile device stand of claim 1, wherein the bladder is formed from latex.

15. The mobile device stand of claim 1, wherein the bladder is formed from rubber.
